(19) United States
(12) Patent Application Publication
(10) Pub. No.: US 2015/0349216 A1
(43) Pub. Date: Dec. 3, 2015

(54) LIGHT EMITTING DIODE PACKAGE STRUCTURE

(71) Applicants: Shih-Yu Chiu, Taoyuan County (TW); Tzung-Shin Li, Taoyuan County (TW); Shao-Han Tan, Taoyuan County (TW); Cheng-Pin Cho, Taoyuan County (TW)

(72) Inventor: Shih-Yu Chiu, TAOYUAN COUNTY (TW)

(21) Appl. No.: 14/729,035

(22) Filed: Jun. 2, 2015

(30) Foreign Application Priority Data
Jun. 3, 2014 (TW) 103119297

(51) Int. Cl. H01L 33/54; H01L 33/62; H01L 33/44; H01L 33/50; H01L 33/24; H01L 33/36; H01L 27/15; H01L 33/56; H01L 33/04

(52) U.S. Cl. CPC H01L 33/54; H01L 33/56; H01L 33/62; H01L 33/44; H01L 33/04; H01L 33/24; H01L 33/36; H01L 27/15; H01L 33/502

(57) ABSTRACT

A light emitting diode package structure includes an encapsulation case, a phosphor layer, a substrate, and a light emitting diode chip. The encapsulation case has an accommodating space. The phosphor layer is coated on a side of the encapsulation case. The substrate is disposed in the accommodating space. The light emitting diode chip is disposed on a first surface of the substrate. A surface of the light emitting diode chip is devoid of being directly covered by a colloid, and the light emitting diode chip and the package housing are separated from each other by a distance.

### TECHNICAL FIELD

The technical field relates to a light emitting diode package structure, particularly to a full-circumference light emitting diode package structure.

### RELATED ART

Since Dr. Shuji Nakamura from Nichia of Japan successes in epitaxial growth on a sapphire substrate GaN material to produce the first mass producible blue light-emitting diode (blue LED) in 1995, complements for the previously available red and green only LED is completed, making the LED to be formally changed to full-color LED. After white LED is developed by mixed light package of the InGaN blue LED and the phosphor powder in 1996, a variety of LED applications are revealed, which introduces LED into human life, and this white LED package so far is still one of the mainstream technologies.

The main purpose of the LED package is to protect the LED, preventing moisture and the touching when in use. By the superior stent cooling structure, the reliability and service life of LED products can be improved. Collocating package outline with good optical design, different light pattern and application can be produced. The main LED packaging product in the industry, according to the package exterior shape, can be classified as Lamp LED, surface mount LED (SMD LED), piranhas LED, plastic grains multiply carrier package LED (PLCC LED), dot matrix encapsulated LED (Digital/Dot Matrix Display LED), a printed circuit board LED (PCB LED), high power LED, and board-connected LED (COB LED), etc. The packaging type varies, and the using of these packages varies as well.

Due to the compact size of the LED, the aforementioned packaging methods are all to fix the LED to a heat conducting stand, and the LED is connected to the stand via a golden wire. In order to protect the golden wire, an encapsulating glue is used to cover the LED from being touched. Because of this structure, the LED has very strong directivity, which restricts the illumination angle within as large as 140 to 150 degrees. Therefore, the LED lighting module designed according to the aforementioned features faces the drawbacks of limited illumination angle, single directional light source, and different illumination property as the traditional lighting source, which make the LED unsuitable for being used in the traditional lighting device. Therefore, except being able to replace the halogens light used as jewelry Lighting, and the MR16 lighting device used in display windows, the LED is not yet popular in the market due to the disadvantages of limited illumination angle and high price of LED lighting. If full-circumference illumination packaging of the LED can be developed, the replacement of the traditional lighting source with the LED can be largely speeded up.

The conventional packaging technique is to fix a single or multiple LEDs onto the heat conductive substrate by a glue. The anode and cathode of the LED are connected to the heat conductive substrate via a gold wire. And then, the LED on the heat conductive substrate is sealed by the glue containing a phosphor powder to protect the LED and generate white light by mixing lights when connected to the electricity. This packaging design uses glues to protect the LED, which makes the LED easy for transportation and the LED design can be changed as the customer's requirement. However, the glue is not good in heat dissipation, and the LED will generate heat when in operation. The heat will decrease the working efficiency and the life of the LED, and the glue accumulates the heat. Therefore, the heat generated by the LED needs to be guided outside and dissipated by the stand. Moreover, the glue can further restrict the illumination angle, which results in the features of the LED after packaging: directivity, surface light source. As a result, these features will lead to a different light pattern as compared to the traditional light source. Therefore, when using in some traditional lighting device, the illumination effect of LED cannot create the same comfort feeling as the traditional light source.

The US patent publication No. U.S. Pat. No. 6,576,488 discloses a light-emitting diode have the phosphor layer deposited on a conductive substrate or a non-conductive substrate by an electrophoresis coated technique, or the phosphor coated sheet directly attached to the LED to enhance the illumination effect of the LED. However, the cost of this electrophoresis coating technology disclosed in this patent is very expensive, which cannot reduce the cost of the LED, and thus the LED manufactured by this method does not have the price advantage. Besides, in the method which attaches phosphor coated sheet onto the LED, the phosphor coated sheet needs to be prepared separately, resulting complicated manufacturing process. In addition, the process attaching the phosphor coated sheet needs to be very precise, and the yield is not easy to control, thereby increasing the cost of the manufacturing process.

Taiwan Patent Publication No. TW201222889 discloses a packaging method using separated phosphor powder. The main difference of this method compared to the traditional packaging method is using multi-layer encapsulating glue to cover the light-emitting diodes. Since the working efficiency of the phosphor powder will attenuate and the color temperature offset can happen under high temperature, and the light-emitting diode itself is the primary source of heat, this patent application uses multilayer package to place the phosphor powder in the outermost layer to enhance the stability of the white light efficiency. However, this approach is not able to solve the directivity problem of the conventional light emitting diode package.

Chinese Patent Publication No. CN103322525 is a LED filament packaging method, the blue light-emitting diode is placed on a transparent substrate, and two ends of the transparent substrate connect the metal conductor to serially connect the anode and the cathode of the light emitting diodes to the metal conductor. And then, a mixture of the phosphor powder and the encapsulating glue is used to seal the entire transparent substrate. By doing so, the full-circumference illumination effect can be achieved. However, the encapsulating glue is still attached to the entire light-emitting diode, which also results in heat dissipating problem and lacks reliability.

In view of the aforementioned disadvantages and problems, based on many years of practical experience and research experiments, and mainly focused on the principles of lighting needs, the inventor redefines a new packaging method which breaks the traditional limitations and shortcomings of the packaging method, and develop a light emitting diode package structure which complies with the application of the lighting.

### BRIEF SUMMARY

An exemplary embodiment of the present invention provides a light emitting diode package structure which has at least one of the advantages of better illumination efficiency, better uniformity of the reflected light, and better full-circumference illumination angle.

The light emitting diode package structure of the exemplary embodiment of the present invention includes an encapsulation case, a phosphor layer, a substrate, and a light emitting diode chip. The encapsulation case has an accommodating space. The phosphor layer is coated on a side of the encapsulation case. The substrate is disposed inside the accommodating space. The light emitting diode chip is disposed on a first surface of the substrate, wherein a surface of the light emitting diode chip is devoid of being directly covered by a colloid. The light emitting diode chip and the encapsulation case are separated from each other by a distance.

In one of the preferred embodiment of the present invention, the encapsulation case includes an opening, the substrate is disposed inside the accommodating space through the opening; a sealing element, disposed at the opening for sealing the substrate and the light emitting diode chip inside the accommodating space.

In one of the preferred embodiment of the present invention, the light emitting diode package structure further comprises a medium, the medium is disposed between the light emitting diode chip and the phosphor layer, wherein the refraction index of the medium is smaller or equal to 1.2.

In one of the preferred embodiment of the present invention, the medium is air.

In one of the preferred embodiment of the present invention, the light emitting diode package structure further comprises a connector electrically connecting to the substrate and the light emitting diode chip, wherein the connector is disposed on the substrate and extends to outside of the opening.

In one of the preferred embodiment of the present invention, the light emitting diode package structure further comprises a wire module formed on the substrate, wherein two wires of the wire module electrically connect the light emitting diode chip and two electrodes of the connector.

In one of the preferred embodiment of the present invention, a material of the sealing element is selected from a group consisting of plastic, ceramics, and epoxy.

In one of the preferred embodiment of the present invention, the substrate is a transparent substrate.

In one of the preferred embodiment of the present invention, a material of the transparent substrate is selected from a group consisting of Sapphire, BK7, MgF₂, AlN, Quartz, SF11, LaSFN9, NSF8, ZnSe, B270, PMMA, Polycarbonate, CaF₂, SiO₂, and Al₂O₃

In one of the preferred embodiment of the present invention, the substrate has a second surface opposite to the first surface, and a plurality of micro structures are disposed on the second surface.

In one of the preferred embodiment of the present invention, the plurality of micro structures are selected from a group consisting of square-shaped, round-shaped, triangle-shaped, hexagon-shaped, cylinder-shaped, conical-shaped, and polygon-shaped micro structures.

In one of the preferred embodiment of the present invention, the light emitting diode chip is invertedly disposed on the substrate.

In one of the preferred embodiment of the present invention, the amount of the light emitting diode chip is plural; the plurality of the light emitting diode chips are serially, parallelly, or serially-parallelly electrically connected to each other.

In one of the preferred embodiment of the present invention, the encapsulation case includes a first opening and a second opening; the substrate is disposed in the accommodating space through either one of the first opening and the second opening.

In one of the preferred embodiment of the present invention, the light emitting diode package structure further comprises a first connector and a second connector electrically connected to the substrate and the light emitting diode chip, wherein the first connector and the second connector are disposed on the substrate and respectively extend to outside of the first opening and the second opening.

In one of the preferred embodiment of the present invention, the light emitting diode package structure further comprises a wire module formed on the substrate, wherein one wire of the wire module electrically connects the light emitting diode chip and one electrode of the first connector; another one wire of the wire module electrically connects the light emitting diode chip and one electrode of the second connector.

In one of the preferred embodiment of the present invention, the light emitting diode package structure further comprises a first connecting element and a second connecting element respectively disposed in the first opening and the second opening for sealing the substrate and the light emitting diode chip in the accommodating space.

In one of the preferred embodiment of the present invention, a material of the encapsulation case is selected from a group consisting of poly methyl methacrylate, polycarbonate, SiO₂, BK7, and glass.

Based on the above, since the surface of the light emitting diode chip is devoid of being directly covered by a colloid, and the light emitting diode chip and the encapsulation case are separated from each other by a distance, better illumination efficiency and better uniformity of the reflected light can be achieved. Besides, by the encapsulation case and the phosphor layer coated on a side of the encapsulation case, the light emitting diode package structure can provide full-circumference illumination angle. Since the light emitting diode package structure can provide full-circumference illumination angle, the light emitting diode package structure can replace the traditional light device without being noticeably different from the conventional one.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 is a longitudinal sectional view of the light emitting diode package structure of a preferred embodiment of the present invention;

FIG. 2 is a side schematic view of FIG. 1;

FIG. 3 is a manufacturing process of the light emitting diode package structure of a preferred embodiment of the present invention;

FIG. 4 is a longitudinal sectional view of the light emitting diode package structure of another preferred embodiment of the present invention;

FIG. 5 is a side schematic view of FIG. 4;

FIG. 6 is a longitudinal sectional view of the light emitting diode package structure of still another preferred embodiment of the present invention;

FIG. 7 is a side schematic view of the light emitting diode package structure of still another preferred embodiment of the present invention;

FIG. 8 is a side schematic view of the light emitting diode package structure of still another preferred embodiment of the present invention;

FIG. 9 is a side schematic view of the light emitting diode package structure of still another preferred embodiment of the present invention; and

FIG. 10 is an arrangement schematic view of the light emitting diode chips of still another embodiment of the present invention.

### DETAILED DESCRIPTION

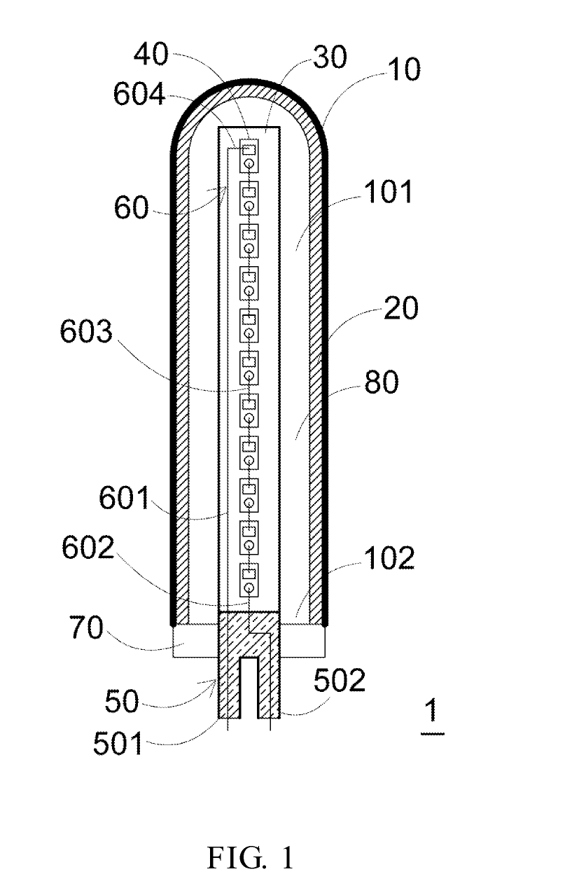

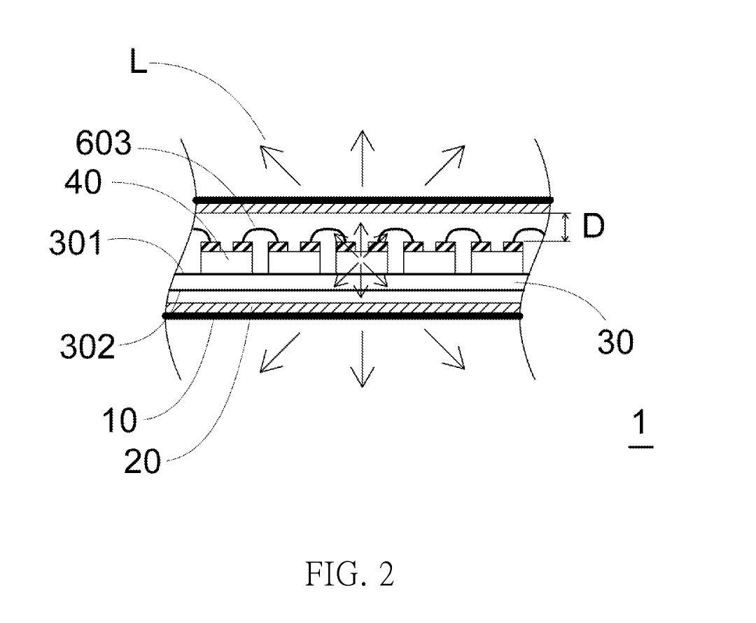

Please refer to FIGS. 1 and 2, in the preferred embodiment of the present invention, the light emitting diode package structure 1 includes an encapsulation case 10, a phosphor layer 20, a substrate 30, and a light emitting diode chip 40. The encapsulation case 10 has an accommodating space 101. The phosphor layer 20 is coated on a side of the encapsulation case 10. The substrate 30 is disposed inside the accommodating space 101. The light emitting diode chip 40 is disposed on a first surface 301 of the substrate 30 and is separated from the phosphor layer 20 by a distance D.

Specifically, in the preferred embodiment of the present invention, a material of the encapsulation case 10 is selected from a group consisting of poly methyl methacrylate, polycarbonate, SiO₂, BK7, and glass. The encapsulation case 10 includes an opening 102. The substrate 30 is disposed inside the accommodating space 101 through the opening 102.

In the preferred embodiment of the present invention, the substrate 30 has a first surface 301 and a second surface 302 opposite to the first surface 301. The substrate 30 can be a transparent substrate, and the first surface 301 is used to load the light emitting diode chip 40. The material of the transparent substrate is selected from a group consisting of Sapphire, BK7, MgF₂, AlN, Quartz, SF11, LaSFN9, NSF8, ZnSe, B270, PMMA, Polycarbonate, CaF₂, SiO₂, and Al₂O₃.

The amount of the light emitting diode chip can be plural; the plurality of the light emitting diode chips are serially, parallelly, or serially-parallelly electrically connected to each other. In the preferred embodiment of the present invention, the plurality of light emitting diode chips are serially electrically connected to each other, but not limited thereto. The main light emission wavelength of the light emitting diode chip 40 is in a range between larger or equal to 400 nm and smaller or equal to 700 nm. The phosphor layer 20 is coated on an inner surface of the encapsulation case 10, and the light emission wavelength of the phosphor layer 20 is between larger or equal to 400 nm and smaller or equal to 700 nm.

The light emitting diode package structure 1 of the preferred embodiment of the present invention further includes a connector 50, a wire module 60, a sealing element 70, and a medium 80. The connector 50 is electrically connected to the substrate 30 and the light emitting diode chip 40, wherein the connector 50 is disposed on the substrate 30 and extends to outside of the opening 102. In one preferred embodiment of the present invention, the opening 102 is formed on one end of the encapsulation case 10. The wire module 60 is formed on the substrate 30, wherein two wires 601/602 of the wire module 60 electrically connect the light emitting diode chip 40 and two electrodes of the connector 50. The sealing element 70 is disposed at the opening 102 for sealing the substrate 30 and the light emitting diode chip 40 into the accommodating space 101 to prevent the substrate 30 and the light emitting diode chip 40 from being damaged by the moisture. The sealing of the sealing element 70 can totally isolate the moisture. The material of the sealing element 70 is selected from a group consisting of plastic, ceramics, and epoxy. The medium 80 is disposed between the light emitting diode chip 40 and the phosphor layer 20, wherein the refraction index of the medium 80 is smaller or equal to 1.2. In a preferred embodiment of the present invention, the medium is air.

Besides, please refer to FIG. 2, in the preferred embodiment of the present invention, when the electricity drives the light emitting diode chip 40, the light emitting diode chip 40 emits a light L. When the light L passes through the phosphor layer 20 coated on one side of the encapsulation case 10, since the surface of the light emitting diode chip 40 is not directly covered with a colloid, and the light emitting diode chip 40 and the encapsulation case 10 are separated from each other by a distance D, better illumination efficiency and better uniformity of the reflected light of the light emitting diode chip 40 can be achieved. Besides, since the phosphor layer 20 is away from the light emitting diode 40 which generates heat, and the phosphor layer 20 does not directly contact the light emitting diode chip 40, the reliability of the light emitting diode package structure 1 can thus be improved, and the manufacturing cost of the light emitting diode package structure 1 being able to be used in multiple light emitting diode chips 40 can be largely decreased. Moreover, by the encapsulation case 10 and the phosphor layer 20 coated on a side of the encapsulation case 10, the light L emitted by the light emitting diode chip 40 can be transformed to white light by passing through the phosphor layer 20, and thus the light emitting diode package structure 1 can provides light emitting diode chip 40 being able to emits full-circumference illumination angle white light. Therefore, the light emitting diode package structure 1 can replace the traditional light device without being noticeably different from the conventional one. Besides, the phosphor layer 20 coated on one side of the encapsulation case 10 can make the mixture of the white light more even, which can improve the color shift happened at the border of the light emitting angle in the conventional light emitting diode package structure.

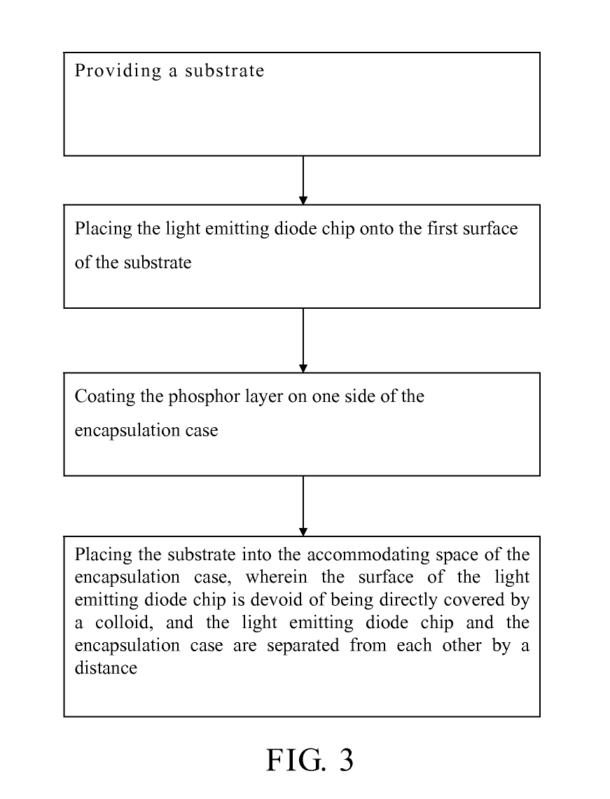

Please refer to FIG. 3, the present preferred embodiment uses the element labels and part of the content of the previous embodiment. The same element labels are used to represent the same or similar contents of the present preferred embodiment, and the same description of the technique detail is omitted. The omitted part can be referred to the previous embodiment, and not repeated hereinafter. Please refer to FIGS. 1-3, in the present preferred embodiment, the manufacturing process of the light emitting diode package structure 1 is described as follows: in step (1), providing a substrate 30; in step (2), placing the light emitting diode chip 40 onto the first surface 301 of the substrate 30; in step (3), coating the phosphor layer 20 on one side of the encapsulation case 10; in step (4), placing the substrate 30 into the accommodating space 101 of the encapsulation case 10, wherein the surface of the light emitting diode chip 40 is devoid of being directly covered by a colloid, and the light emitting diode chip 40 and the encapsulation case 10 are separated from each other by a distance D, thus better illumination efficiency and better uniformity of the reflected light can be achieved. In another preferred embodiment of the present invention, the step (1) and (3) can be interchanged, which means the step (3) firstly proceeds, and then step (2), step (1), and step (4), in sequential order.

Specifically, in step (2) of one preferred embodiment of the present invention, a die bonder machine can be used to bond a plurality of light emitting diode chips 40 onto the substrate 30. Besides, in one preferred embodiment of the present invention, a step (a1) can proceed after the step (1) and before the step (4). In step (a1), a wire 601 of the wire module 60 can be disposed on the substrate 30. The manufacture of the wire 601 can be done by printing, electroplating, vacuum electroplating, or chemical electroplating, or photolithography, vacuum vapor deposition, etching, or stripping process of the semiconductor to complete the manufacturing of the delicate wiring for bonding the dies on the substrate 30. After the step (a1), the step (a2) is executed. In step (2), providing the connector 50; the connector 50 is disposed on the substrate 30 for electrically connecting to the electricity.

Besides, a step (b) can be executed after step (2). In step (b), connecting a plurality of light emitting diode chips 40 together with a wire 603 by wire bonding process. In one preferred embodiment of the present invention, the wire 603 can be gold material or aluminum material, and the wire 603 can serially or parallelly connect a plurality of light emitting diode chips 40. The way of connection can be adjusted as required. In one preferred embodiment of the present invention, a step (c) can be executed after the step (b) and step (a2). In step (c), connecting the connector 50 with a wire 602 by wire bonding process, and further connecting the wire 601 to the wire 604. A step (5) can be executed after the step (4). In step (5), providing sealing element 70 for sealing the substrate 30 and the light emitting diode chip 40 into the accommodating space 101 to prevent the substrate 30 and the light emitting diode chip 40 from being damaged by the moisture. The sealing element 70 can totally isolate the moisture. The encapsulation case 10 and the sealing element 70 can prevent the light emitting diode chip 40 from being touched. Therefore, the light emitting diode package structure 1 of the preferred embodiment of the present invention does not need an encapsulating glue to cover thereon, thereby resolving the problem of heat dissipating, the directionality of the light source, and the surface light source.

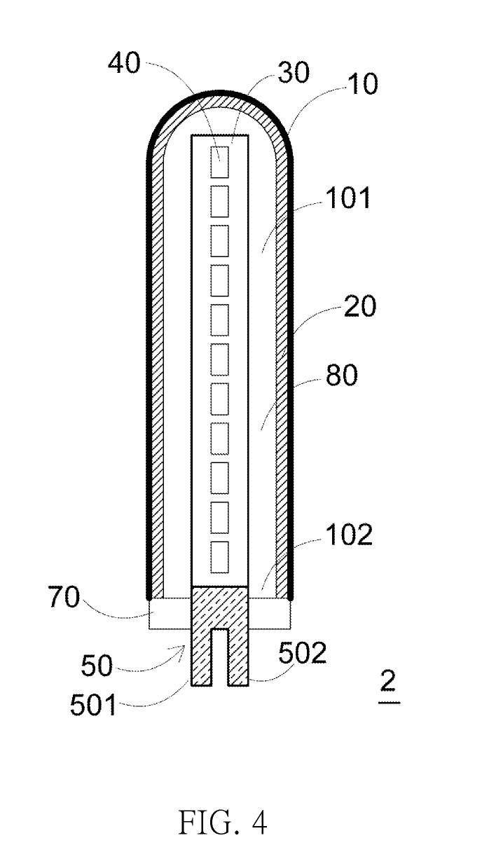

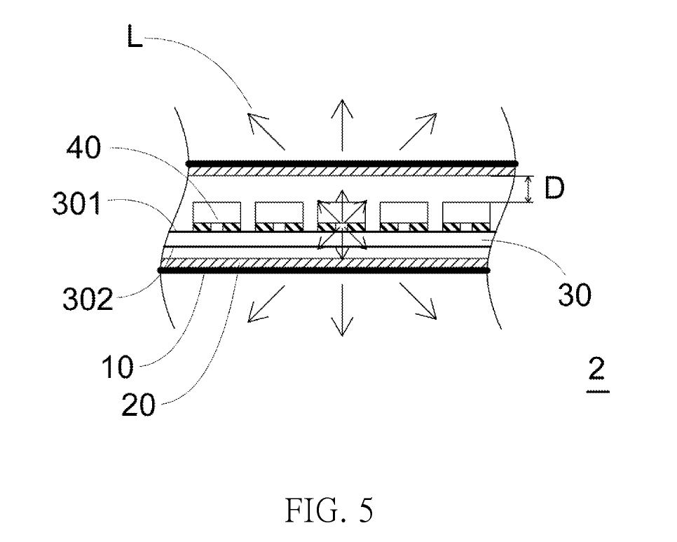

Referring to FIGS. 4 and 5, the present preferred embodiment uses the element labels and part of the content of the previous embodiment. The same element labels are used to represent the same or similar contents of the present preferred embodiment, and the same description of the technique detail is omitted. The omitted part can be referred to the previous embodiment, and not repeated hereinafter. The main difference of the light emitting diode package structure 2 and the previous light emitting diode package structure 1 is that the light emitting diode chip 40 is invertedly disposed on the substrate 30. Specifically, the wiring manufactured on the substrate 30 can decide the way that the light emitting diode chip 40 is connected, such as serially connecting or parallelly connecting. The invertedly disposed light emitting diode chip 40 uses the wire to get connected to the electricity and emit the light. By using the flip-chip process, the light emitting diode chip 40 is invertedly disposed on the top of the substrate 30, and the problem that the heat accumulation on the die bonding glue used to bond the light emitting diode to the substrate 30 can be solved. In the preferred embodiment of the present invention, by the arrangement of invertedly placing the light emitting diode chip 40 on the substrate 30, the heat dissipating efficiency of the light emitting diode chip 40 is improved, and so do the light emission efficiency and the durability.

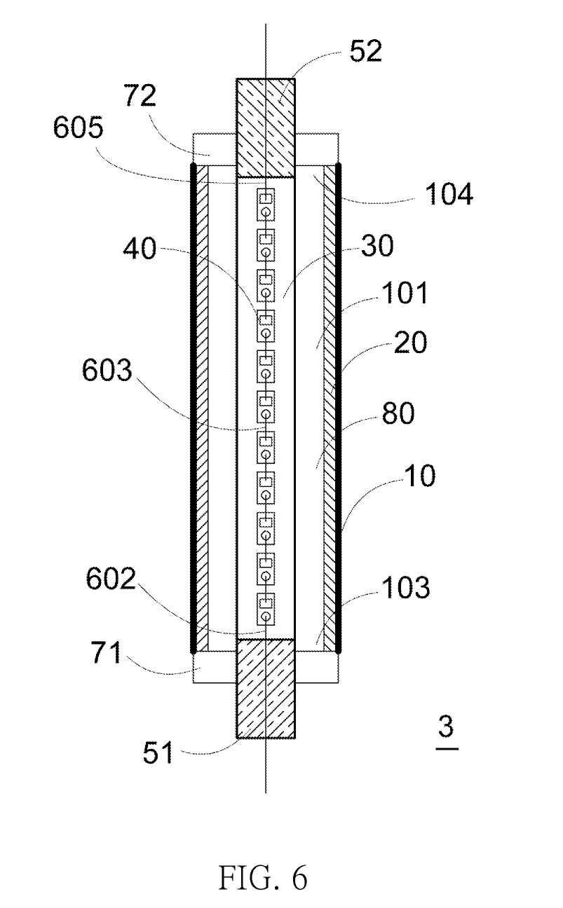

Please refer to FIG. 6, the present preferred embodiment uses the element labels and part of the content of the previous embodiment. The same element labels are used to represent the same or similar contents of the present preferred embodiment, and the same description of the technique detail is omitted. The omitted part can be referred to the previous embodiment, and not repeated hereinafter. The main difference of the light emitting diode package structure 3 and the previous light emitting diode package structure 1 is that the encapsulation case 10 further includes a first opening 103 and a second opening 104. The substrate 30 is disposed inside the accommodating space 101 through either one of the first opening 103 and the second opening 104. In the preferred embodiment of the present invention, the first opening 103 and the second opening 104 can respectively be disposed at two opposite ends of the encapsulation case 10, but not limited thereto. The first connector 51 and the second connector 52 are electrically connected to the substrate 30 and the light emitting diode chip 40, wherein the first connector 51 and the second connector 52 are disposed on the substrate 30 and respectively extend to outside of the first opening 103 and the second opening 104. The wire module 60 is formed on the substrate 30, wherein a wire 602 of the wire module 60 electrically connects the light emitting diode chip 40 and an electrode of the first connector 51; a wire 605 of the wire module 60 electrically connects the light emitting diode chip 40 and an electrode of the second connector 52. In the preferred embodiment of the present invention, the first connector 51 and the second connector 52 can be a direct current power source, the electrodes of the first connector 51 and the second connector 52 can be an anode and a cathode, respectively. By the layout of the connection, the light emitting diode chip 40 can be connected to the anode and the cathode of the direct current power source, which makes the light emitting diode package structure 3 is more versatile and convenient to use. A first connecting element 71 and a second connecting element 72 are respectively disposed at the first opening 103 and the second opening 104 for sealing the substrate 30 and the light emitting diode chip 40 inside the accommodating space 101 to prevent the substrate 30 and the light emitting diode chip 40 from being damaged by the moisture. The sealing of the first connecting element 71 and the second connecting element 72 can totally isolate the moisture. The encapsulation case 10, the first connecting element 71 and the second connecting element 72 can prevent the light emitting diode chip 40 from being touched. Therefore, the light emitting diode package structure 3 of the preferred embodiment of the present invention does not need an encapsulating glue to cover thereon, thereby resolving the problem of heat dissipating, the directionality of the light source, and the surface light source.

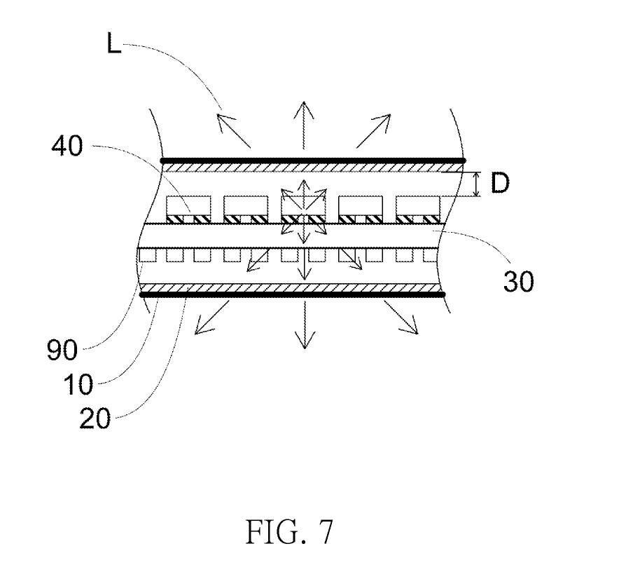

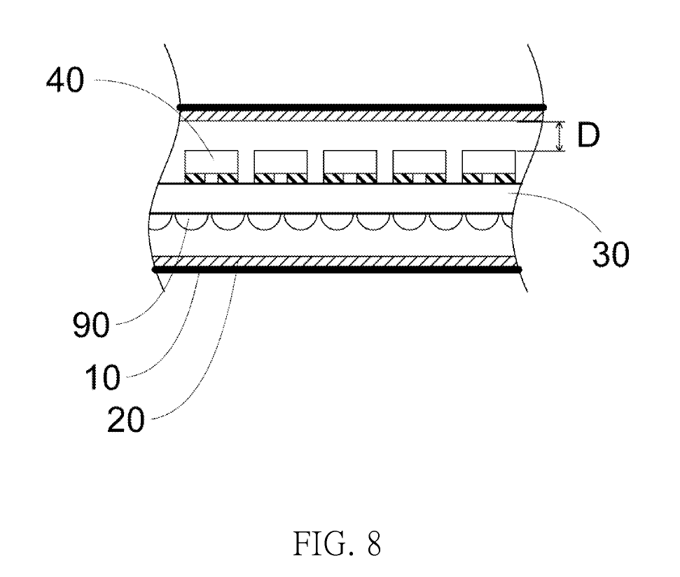

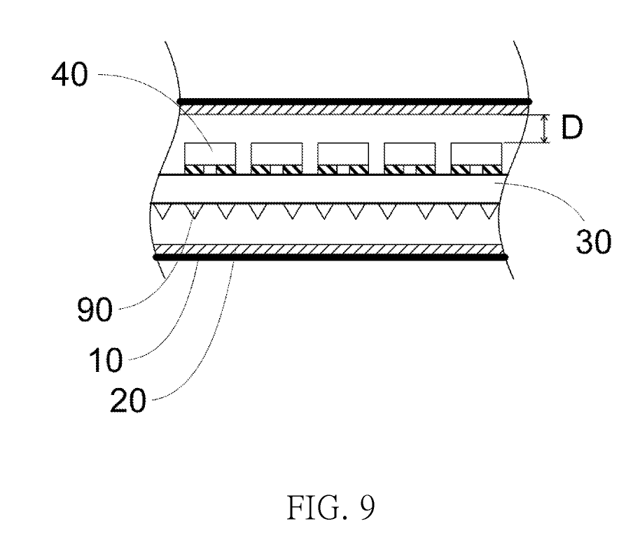

Please refer to FIGS. 7-9, the present preferred embodiment uses the element labels and part of the content of the previous embodiment. The same element labels are used to represent the same or similar contents of the present preferred embodiment, and the same description of the technique detail is omitted. The omitted part can be referred to the previous embodiment, and not repeated hereinafter. The second surface 302 of the substrate 30 is provided with a plurality of micro structures 90. The plurality of micro structures can be selected from a group consisting of square-shaped (FIG. 7), round-shaped (FIG. 8), triangle-shaped (FIG. 8), hexagon-shaped, cylinder-shaped, conical-shaped, and polygon-shaped micro structures. These micro structures 90 can be disposed as periodic arrangement. When the light L passes through different materials, problems of the light emitting angle can be caused due to the different refractive index between two different materials. The light will be restricted inside the material if the light is emitted larger than the light emitting angle. The restricted light can only be led out of the material by creating different planes on the illuminating surface for the restricted light L to escape. By these micro structures 90, the critical angle can be altered when the light L passes through the substrate 30, and thus the light emitting efficiency and the light mixing efficiency can be improved as well.

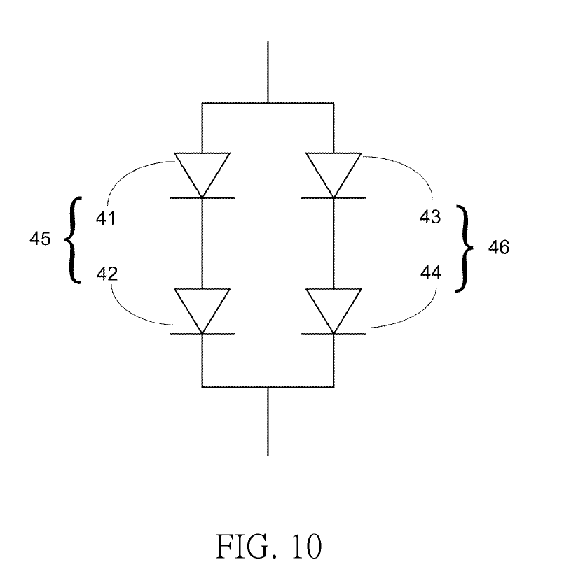

Please refer to FIG. 10, in the preferred embodiment of the present invention, the light emitting diode chips 40 are serially and parallelly electrically connected to each other, but not limited thereto. In other preferred embodiments, the light emitting diode chips 40 can be serially or parallelly electrically connected to each other. Specifically, in the preferred embodiment of the present invention, the light emitting diode chips 41 and 42 are serially connected to form a light emitting diode chip set 45; the light emitting diode chips 43 and 44 are serially connected to form a light emitting diode chip set 46. The light emitting diode chip sets 45 and 46 are parallelly connected. By the serially, parallelly, or serially-parallelly connecting of the light emitting diode chips 40, the light emitting diode package structure is more versatile and convenient to use.

In summary, since the surface of the light emitting diode chip 40 is devoid of being directly covered by a colloid, and the light emitting diode chip 40 and the encapsulation case 10 are separated from each other by a distance D, better illumination efficiency and better uniformity of the reflected light can be achieved. Besides, since the phosphor layer 20 is away from the light emitting diode 40 which generates heat, and the phosphor layer 20 does not directly contact the light emitting diode chip 40, the reliability of the light emitting diode package structure 1 can thus be improved, and the manufacturing cost of the light emitting diode package structure 1 being able to be used in multiple light emitting diode chips 40 can be largely decreased. Besides, by the encapsulation case 10 and the phosphor layer 20 coated on a side of the encapsulation case 10, the light emitting diode package structure 1 can provide full-circumference illumination angle. Since the light emitting diode package structure 1 can provide full-circumference illumination angle, the light emitting diode package structure 1 can replace the traditional light device without being noticeably different from the conventional one. Besides, the phosphor layer 20 coated on one side of the encapsulation case 10 can make the mixture of the white light more even, which can improve the color shift happened at the border of the light emitting angle in the conventional light emitting diode package structure.

Although the present invention has been described with reference to the foregoing preferred embodiments, it will be understood that the invention is not limited to the details thereof. Various equivalent variations and modifications can still occur to those skilled in this art in view of the teachings of the present invention. Thus, all such variations and equivalent modifications are also embraced within the scope of the invention as defined in the appended claims.

What is claimed is:

1. A light emitting diode package structure, comprising:
an encapsulation case provided with an accommodating space therein;
a phosphor layer coated on a side of the encapsulation case;
a substrate disposed inside the accommodating space; and
a light emitting diode chip disposed on a first surface of the substrate, wherein a surface of the light emitting diode chip is devoid of being directly covered by a colloid; the light emitting diode chip and the encapsulation case are separated from each other by a distance.

2. The light emitting diode package structure according to claim 1, wherein the encapsulation case includes:
an opening, the substrate being disposed inside the accommodating space through the opening; a sealing element disposed at the opening for sealing the substrate and the light emitting diode chip inside the accommodating space.

3. The light emitting diode package structure according to claim 2 further comprising a medium, the medium being disposed between the light emitting diode chip and the phosphor layer, wherein the refraction index of the medium is smaller or equal to 1.2.

4. The light emitting diode package structure according to claim 3, wherein the medium is air.

5. The light emitting diode package structure according to claim 2, further comprising a connector electrically connecting to the substrate and the light emitting diode chip, wherein the connector is disposed on the substrate and extends to outside of the opening.

6. The light emitting diode package structure according to claim 5, further comprising a wire module formed on the substrate, wherein two wires of the wire module electrically connect the light emitting diode chip and two electrodes of the connector.

7. The light emitting diode package structure according to claim 2, wherein a material of the sealing element is selected from a group consisting of plastic, ceramics, and epoxy.

8. The light emitting diode package structure according to claim 1, wherein the substrate is a transparent substrate.

9. The light emitting diode package structure according to claim 8, wherein a material of the transparent substrate is selected from a group consisting of Sapphire, BK7, MgF₂, AlN, Quartz, SF11, LaSFN9, NSF8, ZnSe, B270, PMMA, Polycarbonate, CaF₂, SiO₂, and Al₂O₃.

10. The light emitting diode package structure according to claim 8, wherein the substrate has a second surface opposite to the first surface, and a plurality of micro structures are disposed on the second surface.

11. The light emitting diode package structure according to claim 10, wherein the plurality of micro structures are selected from a group consisting of square-shaped, round-shaped, triangle-shaped, hexagon-shaped, cylinder-shaped, conical-shaped, and polygon-shaped micro structures.

12. The light emitting diode package structure according to claim 1, wherein the light emitting diode chip is invertedly disposed on the substrate.

13. The light emitting diode package structure according to claim 1, wherein the amount of the light emitting diode chip is plural; the plurality of the light emitting diode chips are serially, parallelly, or serially-parallelly electrically connected to each other.

14. The light emitting diode package structure according to claim 1, wherein the encapsulation case includes a first opening and a second opening; the substrate is disposed in the accommodating space through either one of the first opening and the second opening.

15. The light emitting diode package structure according to claim 14, further comprising a first connector and a second connector electrically connected to the substrate and the light emitting diode chip, wherein the first connector and the second connector are disposed on the substrate and respectively extend to outside of the first opening and the second opening.

16. The light emitting diode package structure according to claim 13, further comprising a first connecting element and a second connecting element respectively disposed in the first opening and the second opening for sealing the substrate and the light emitting diode chip in the accommodating space.

17. The light emitting diode package structure according to claim 1, wherein a material of the encapsulation case is selected from a group consisting of poly methyl methacrylate, polycarbonate, SiO₂, BK7, and glass.
